(19) United States
(12) Patent Application Publication
(10) Pub. No.: US 2015/0363261 A1
(43) Pub. Date: Dec. 17, 2015

(54) RAM REFRESH RATE

(71) Applicant: Hewlett-Packard Development Company, L.P., Houston, TX (US)

(72) Inventors: Lidia Warnes, Roseville, CA (US); Andrew C Walton, Rocklin, CA (US)

(21) Appl. No.: 14/764,210

(22) PCT Filed: Jan. 31, 2013
(86) PCT No.: PCT/US13/24233

§ 371 Date: Jul. 29, 2015

(51) Int. Cl. G06F 11/10; G11C 29/42; G11C 29/20; G11C 29/50

(52) U.S. Cl. CPC G06F 11/106; G11C 29/50004; G11C 29/42; G11C 29/20; G11C 2029/5004

(57) ABSTRACT

A refresh rate of a random-access memory (RAM) is increased if a number of errors is greater than an error threshold and the refresh rate has not reached a maximum rate. The refresh rate of the RAM is set to a normal rate if the number of errors is less than or equal to the error threshold.

### BACKGROUND

As a complexity of memory devices increase, the memory devices may become increasingly prone to data errors. For example, some types of data access patterns may cause leakage between word lines of a memory, resulting in loss or corruption of data. Manufacturers and/or vendors may be challenged to reduce a likelihood of data errors for the memory devices while minimizing latency and/or performance degradation of the memory devices.

### BRIEF DESCRIPTION OF THE DRAWINGS

The following detailed description references the drawings, wherein:

FIG. 1 is an example block diagram of a device to change a refresh rate of RAM based on a number of errors;

FIG. 2 is another example block diagram of a device to change a refresh rate of RAM based on a number of errors;

FIG. 3 is an example block diagram of a computing device including instructions for changing a refresh rate of RAM based on a number of errors; and

FIG. 4 is an example flowchart of a method for changing a refresh rate of RAM based on a number of errors.

### DETAILED DESCRIPTION

Specific details are given in the following description to provide a thorough understanding of embodiments. However, it will be understood that embodiments may be practiced without these specific details. For example, systems may be shown in block diagrams in order not to obscure embodiments in unnecessary detail. In other instances, well-known processes, structures and techniques may be shown without unnecessary detail in order to avoid obscuring embodiments.

Memory devices are increasing in complexity as the die features size of the memory devices decreases and the storage capacity of the memory devices increases. As a result, failure mechanisms encountered in a memory device are becoming more complex as well. One type of problem encountered by the memory devices are “storms” of correctible, transient errors caused by leakage between word lines, which carry the row address information in a dynamic random access memory (DRAM). These error storms are caused by repeated accesses to a culprit word line, which may result in data being corrupted in word lines physically adjacent to the culprit word line. At a higher level, such as a system level where the memory devices are integrated, a user may have little to no control over stressful or malicious application behavior that exploits the memory device's weakness and causes such error storms.

A memory subsystem of the memory device may check for data errors periodically. Thus, these transient errors may be corrected by a chipset and/or a Basic Input/Output System (BIOS), but if the error storm continues, it may have the following negative effects on the system. For example, a user may be notified to replace hardware to eliminate the errors, which would result in system downtime and/or customer dissatisfaction. Further, the system may crash if too many transient errors cause an uncorrectable event. In a small number of cases, random transient errors may cause silent data corruption. Also, system performance may be impacted because a processor communicating to the memory device(s) may spend time correcting errors instead of executing applications.

Embodiments, may disrupt data patterns that cause the error storms and increase system reliability by reducing an error rate associated with the word line leakage weakness in memory, such as DRAM, by dynamically changing a memory refresh rate. For example, a detection unit may count a number of cells of a random-access memory (RAM) that have errors. A threshold unit may determine a refresh rate of the RAM based on the number of cells having errors and an error threshold. The threshold unit may increase the refresh rate of the RAM if the number of errors is greater than an error threshold and the refresh rate is not at a maximum rate. The threshold unit may return the refresh rate of the RAM to a normal rate if the number of errors is less than or equal to the error threshold.

Increasing the memory refresh rate disrupts the memory access pattern that creates the error storm by inserting refresh cycles. Also, each refresh restores a state cells in the RAM, such as DRAM, to a known good state and eliminates potential harmful amounts of charge accumulated in the device substrate that can cause transient memory errors. Further, embodiments may limit a performance impact associated with an increased memory refresh rate by accounting for a tendency of errors storms to be bursty. For example, the refresh rate is increased only for a period of time that is effective for lowering the number of errors, and then lowered back to a normal rate between error storms.

Thus, embodiments may reduce or eliminate memory errors associated with the word line leakage issue while reducing or minimizing a performance impact. Warranty costs and downtime may also be reduced for users who are exposed to the error storms associated with the word line leakage issue. At a same time, there will be no performance impact for the users who are not exposed to the word line leakage issue, because a broad brush approach is not applied that would always increase the refresh rate and cause performance to be reduced for all the users.

Instead, the performance impact is limited only to times when users experience bursty error storms by increasing the refresh rate only when necessary. In addition, embodiments may allow a system designer to work with a user who has an application that causes the word line leakage issue. For example, the increased refresh rate caused by embodiments can be detected. Then the application which causes the error storm can be detected and modified to reduce or eliminate the error storm.

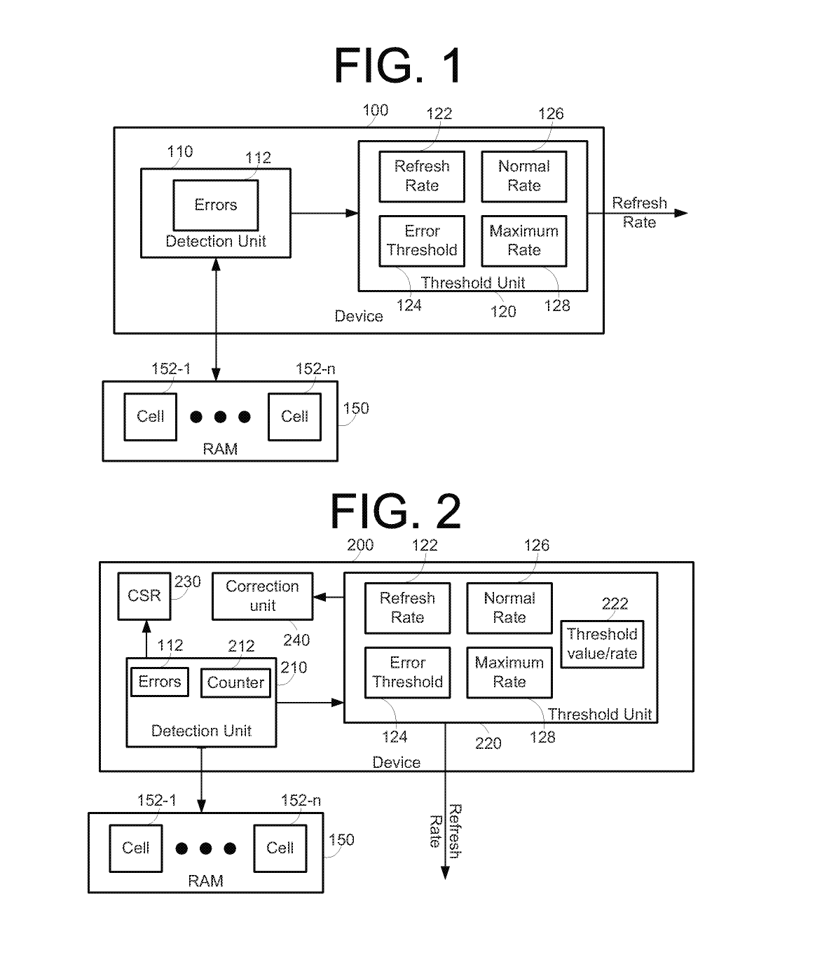

Referring now to the drawings, FIG. 1 is an example block diagram of a device 100 to change a refresh rate 122 of RAM 150 based on a number of errors 112. The device 100 may be any type of device related to controlling a refresh rate of memory, such as a memory controller, a microprocessor, memory circuitry, an integrated circuit (IC) and the like. In the embodiment of FIG. 1, the device 100 includes a detection unit 110 and a threshold unit 120. Further, the device 100 interfaces with a RAM 150. The RAM 150 may be, for example, a dynamic RAM (DRAM), and have a plurality of memory cells 152-1 to 152-n, where n is a natural number.

The term refresh rate may refer to a number of refresh cycles within a time period. Each memory refresh cycle refreshes a succeeding area of memory cells, thus refreshing all the cells in a round-robin fashion. The term refresh may refer to a process of periodically reading information from an area of the memory, such as DRAM, and immediately rewriting the read information to the same area without modification, for the purpose of preserving the information. In a DRAM chip, the refresh rate may refer to an interval between each row of DRAM being refreshed, such as one row every 7.8 microseconds (μs). While a refresh cycle is occurring the memory may not be available for normal read and write operations.

The detection and threshold units 110 and 120 may include, for example, a hardware device including electronic circuitry for implementing the functionality described below, such as control logic and/or memory. In addition or as an alternative, the detection and threshold units 110 and 120 may be implemented as a series of instructions encoded on a machine-readable storage medium and executable by a processor.

The detection unit 110 is to count a number of cells 152-1 to 152-n of a random-access memory (RAM) that have errors 112. For example, the detection unit 110 may detect the errors 112 by checking error-correcting codes (ECC) of the memory cells 152-1 to 152-n. The detection unit 110 may count the number of errors 112 according to, for example, a moving average and/or a total number of errors. The total number of errors may be recalculated after the refresh rate 122 is changed. For instance, if the number of errors 112 is calculated according to a moving average, a number of errors within the last 3 minutes may be used. However, if the number of errors 112 is calculated according to total number of errors, the number of errors may continue to be counted until the refresh rate 122 changes. At this point, the number of errors 112 may be reset to start from zero again. The detected errors 112 may be soft, correctible errors that are detected while the device 100 is an active state, as opposed to a sleep or an inactive state.

The threshold unit 120 may determine a refresh rate 122 of the RAM 150 based on the number of cells 152-1 to 152-n having errors 112 and an error threshold 124. For example, the threshold unit 120 may increase the refresh rate 122 of the RAM 150 if the number of errors 112 is greater than an error threshold 124 and the refresh rate 122 has not yet reached a maximum rate 128. The error threshold 124 and the maximum rate 128 may depend on the chipset and/or BIOS capabilities and may be user defined. The error threshold 124 may be, for example, approximately between 10 and 100 errors. The maximum rate 128 may be based on a capability of a chipset (not shown) of the device 100.

The threshold unit 120 is to return the refresh rate 122 of the RAM 150 to a normal rate 126 if the number of errors 122 is less than or equal to the error threshold 124. The normal rate 126 may be, for example, 7.8 μs. The normal rate 126 and/or the error threshold 124 may be set based on a user's performance requirements. The detection and threshold units 110 and 120 may operate autonomously and/or independently of a main processor (not shown) of the device 100. While the RAM 150 is shown to be external to the device 100, embodiments may also include the RAM 150 being internal to the device 100. By increasing the refresh rate 122 when a burst of errors is detected and resetting the refresh rate 122 after the burst of errors subsides, embodiments may reduce a number of errors caused by error storms while limiting an effect on performance.

FIG. 2 is another example block diagram of a device 200 to change a refresh rate 122 of RAM 150 based on a number of errors 112. The device 100 may be any type of device related to controlling a refresh rate of memory, such as a memory controller, a microprocessor, memory circuitry, an integrated circuit (IC) and the like. The device 200 of FIG. 2 may include at least the functionality and/or hardware of the device 100 of FIG. 1. For example, a detection unit 210 and a threshold unit 220 included in the device 200 of FIG. 2 may respectively include the functionality of the detection unit 110 and the threshold unit 120 included in the device 100 of FIG. 1. Further, the device 200 of FIG. 2 also includes a Control and Status Register (CSR) 230 and a correction unit 240.

The CSR 230 and correction unit 240 may include, for example, a hardware device including electronic circuitry for implementing the functionality described below, such as control logic and/or memory. In addition or as an alternative, the CSR 230 and correction unit 240 may be implemented as a series of instructions or microcode encoded on a machine-readable storage medium and executable by a processor.

In FIG. 2, the detection unit 210 may poll the RAM 150 for the errors 112, such as every 1 to 5 minutes. An interval between polls may be based on at least one of reliability requirements and error storage capabilities. The detection unit 210 may include a counter 212 that is incremented by a number of the errors detected after the RAM 150 is polled. The detection unit 210 may also write to the CSR 230 after the errors are detected. The CSR 230 may be used by other components, such as the correction unit 240, to determine if there are errors 112.

The threshold unit 220 may increase the refresh rate 122 according to various methods. In one embodiment, the threshold unit 220 may multiply the normal rate 126 by a threshold value 222 to increase the refresh rate 122. For example, if the normal and refresh rates 122 and 124 are 1 row per 7.8 μs and the threshold value 222 is 2, the threshold unit 220 may multiply 1 row per 7.8 μs by 2 to increase the refresh rate 122 from 1 row every 7.8 μs to 2 rows every 7.8 μs.

In other embodiment, the threshold unit 220 may add a threshold rate 222 to the refresh rate 122 to increase the refresh rate 122. For example, if the refresh rate 122 is 1 row per 7.8 μs and the threshold rate 222 is 0.5 rows per 7.8 μs, the threshold unit 220 may add 0.5 rows per 7.8 μs to 1 row per 7.8 μs to increase the refresh rate 122 from 1 row every 7.8 μs to 1.5 rows every 7.8 μs.

After the RAM 150 has been refreshed at the increased refresh rate 122, the detection unit 210 may again count the number of errors 112. If the number of errors 112 is still greater than the error threshold 124 and the refresh rate 122 has not reached the maximum rate 128, the threshold unit 220 may further increase the refresh rate 122. In one instance, the threshold unit 220 may increase the threshold value 222, such as from 2 to 3. In this case, the threshold unit 220 may multiply the normal rate 126, such as 1 row per 7.8 μs, by 3 to increase the refresh rate 122 from 2 rows every 7.8 μs to 3 rows every 7.8 μs. In another instance, the threshold unit 220 may again add the threshold rate 222, such as 0.5 rows per 7.8 μs, to the existing refresh rate 122, such as 1.5 rows per 7.8 μs, to increase the refresh rate 122 to 2 rows every 7.8 μs.

However, the number of errors 112 may have instead decreased after the RAM 150 has been refreshed at the increased refresh rate 122. In this case, if the number errors 112 is now less than or equal to the error threshold 124, the threshold unit 222 may reset the refresh rate 122 by resetting the threshold value 222, such as to 1, or overwriting the existing refresh rate 122 with the normal rate 126, such as 1 row every 7.8 μs.

In a situation where the number of errors 112 is greater than the error threshold 124 and the refresh rate 122 has reached the maximum rate 128, the detection unit 220 may simply allow the correction unit 240 to correct the errors 112. This is because the errors 112 persisting in such a high number, even after the highest allowable refresh rate 122 has been reached, may indicate that the errors 112 are due to causes other than a transient error storm. In this case, the correction unit 240 may use a memory subsystem redundancy capability or mechanism to correct the errors 112, such as chip spare, rank spare, mirroring and the like.

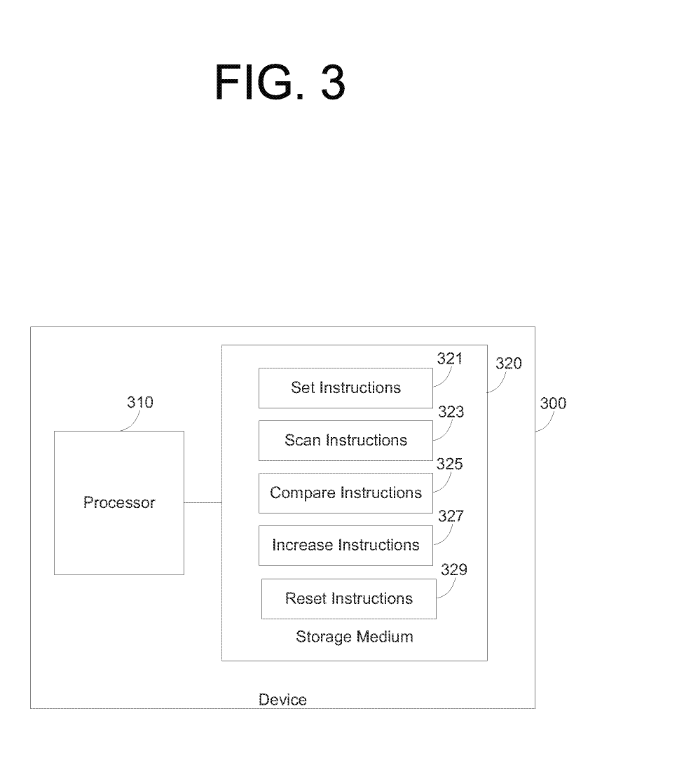

FIG. 3 is an example block diagram of a computing device 300 including instructions for changing a refresh rate of RAM based on a number of errors. In the embodiment of FIG. 3, the computing device 300 includes a processor 310 and a machine-readable storage medium 320. The machine-readable storage medium 320 further includes instructions 321, 323, 325, 327 and 329 for changing the refresh rate of a RAM (not shown) based on a number of errors.

The computing device 300 may be, for example, a secure microprocessor, a notebook computer, a desktop computer, an all-in-one system, a server, a network device, a controller, a wireless device, or any other type of device capable of executing the instructions 321, 323, 325, 327 and 329. In certain examples, the computing device 300 may include or be connected to additional components such as memories, controllers, etc.

The processor 310 may be, at least one central processing unit (CPU), at least one semiconductor-based microprocessor, at least one graphics processing unit (GPU), a microcontroller, special purpose logic hardware controlled by microcode or other hardware devices suitable for retrieval and execution of instructions stored in the machine-readable storage medium 320, or combinations thereof. The processor 310 may fetch, decode, and execute instructions 321, 323, 325, 327 and 329 to implement changing the refresh rate of the RAM based on the number of errors. As an alternative or in addition to retrieving and executing instructions, the processor 310 may include at least one integrated circuit (IC), other control logic, other electronic circuits, or combinations thereof that include a number of electronic components for performing the functionality of instructions 321, 323, 325, 327 and 329.

The machine-readable storage medium 320 may be any electronic, magnetic, optical, or other physical storage device that contains or stores executable instructions. Thus, the machine-readable storage medium 320 may be, for example, Random Access Memory (RAM), an Electrically Erasable Programmable Read-Only Memory (EEPROM), a storage drive, a Compact Disc Read Only Memory (CD-ROM), and the like. As such, the machine-readable storage medium 320 can be non-transitory. As described in detail below, machine-readable storage medium 320 may be encoded with a series of executable instructions for changing the refresh rate of the RAM based on the number of errors.

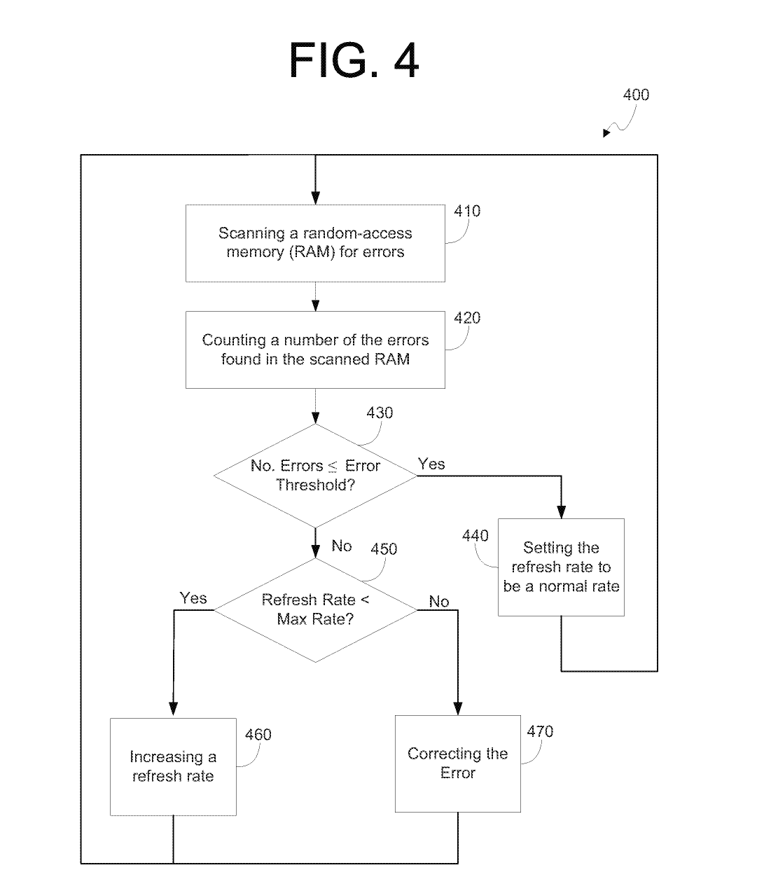

Moreover, the instructions 321, 323, 325, 327 and 329 when executed by a processor (e.g., via one processing element or multiple processing elements of the processor) can cause the processor to perform processes, such as, the process of FIG. 4. For example, the set instructions 321 may be executed by the processor 310 to set the refresh rate at a normal rate. The scan instructions 323 may be executed by the processor 310 to scan the RAM for errors, where each error is to indicate a memory cell of the RAM that stores incorrect data. The compare instructions 325 may be executed by the processor 310 to compare a total number of errors in the RAM to an error threshold. The increase instructions 327 may be executed by the processor 310 to increase the refresh rate if the total number of errors is greater than the error threshold and refresh rate is less than a maximum rate. The reset instructions 329 may be executed by the processor 310 to reset the refresh rate to the normal rate if the total number of errors is less than or equal to the error threshold.

The RAM may be scanned again for errors after the refresh rate is increased. Further, the total number of errors may be compared to the error threshold after the refresh rate is increased. The refresh rate may be increased by a multiple of the normal rate. The multiple may increase in value if the total number of errors remains greater than the error threshold after the refresh rate is increased. For example, if the increase instructions 327 set the refresh rate to be double the normal rate but the subsequently calculated total number of errors remains greater than the error threshold, the increase instructions 327 may then set the refresh rate to be triple the normal rate, assuming the refresh rate is less than the maximum rate.

FIG. 4 is an example flowchart of a method 400 for changing a refresh rate of RAM based on a number of errors. Although execution of the method 400 is described below with reference to the device 200, other suitable components for execution of the method 400 can be utilized, such as the device 100. Additionally, the components for executing the method 400 may be spread among multiple devices (e.g., a processing device in communication with input and output devices). In certain scenarios, multiple devices acting in coordination can be considered a single device to perform the method 400. The method 400 may be implemented in the form of executable instructions stored on a machine-readable storage medium, such as storage medium 320, and/or in the form of electronic circuitry.

At block 410, a detection unit 110 of the device 200 scans a random-access memory (RAM) 150 for errors 112. Then, at block 420, the detection unit 110 counts a number of the errors 112 found in the scanned RAM 150 and transmits the number of errors 112 to a threshold unit 120 of the device 200. The threshold unit 120, at block 430, compares the number of errors 112 to an error threshold 124.

If the threshold unit 120 determines that the number of errors 112 is less than or equal to the error threshold 124 at block 430, the threshold unit 120 sets the refresh rate 122 to be a normal rate 126 (or maintains the refresh rate 122 if it is already at the normal rate 126), at block 440. Then, the method 400 flows back to block 410, where the detection unit 110 continues to scan the RAM 150 for errors.

On the other hand, if the threshold unit 120 determines that the number of errors 112 is greater than the error threshold 124 at block 430, then the threshold unit 120 compares the refresh rate 112 to a maximum rate 128, at block 450. If the threshold unit 120 determines that the refresh rate 122 is less than the maximum rate 128 at block 450, the threshold unit 120 increases the refresh rate 122 at block 460. However, if the threshold unit 120 determines that the refresh rate 122 is greater than or equal to the maximum rate 128 at block 450, the threshold unit 120 signals a correction unit 204. The correction unit 204 then corrects the errors 112 at block 470, such as via a memory subsystem redundancy mechanism. The method 400 flows back to block 410 after blocks 460 and 470.

Thus, the scanning and counting at blocks 410 and 420 are repeated after the increasing at blocks 460 and 470. Moreover, the increasing at block 460 is repeated if the number of errors 122 stays above the error threshold at block 430 and the refresh rate 122 is less than the maximum rate 128 at block 450. Further, the scanning and the counting at blocks 410 and 420 are repeated at continuous intervals after the setting at block 440, if the number of errors 112 at block 430 remains below or equal to the error threshold 124.

According to the foregoing, embodiments provide a method and/or device for disrupting data patterns that cause the error storms by reducing an error rate associated with the word line leakage weakness in memory, such as DRAM, based on dynamically increasing a memory refresh rate. Further, embodiments may limit a performance impact associated with the increased memory refresh rate by accounting for a tendency of errors storms to be bursty. For example, the refresh rate is increased only for a period of time that is effective for lowering the number of errors, and then lowered back to a normal rate between error storms.

We claim:

1. A device, comprising:
a detection unit to count a number of cells of a random-access memory (RAM) that have errors; and
a threshold unit to determine a refresh rate of the RAM based on the number of cells having errors and an error threshold, wherein
the threshold unit is to increase the refresh rate of the RAM if the number of errors is greater than an error threshold and the refresh rate has not reached a maximum rate, and
the threshold unit is to return the refresh rate of the RAM to a normal rate if the number of errors is less than or equal to the error threshold.

2. The device of claim 1, wherein,
the threshold unit is to increase the refresh rate by at least one of multiplying the normal rate by a threshold value and adding a threshold rate to the refresh rate,
the threshold value is to be increased each time the threshold unit increases the refresh rate, and
the threshold unit is to reset the threshold value if the threshold unit returns the refresh rate of the RAM to a normal rate.

3. The device of claim 1, further comprising:
a correction unit to correct the errors if the number of errors is greater than the error threshold and the refresh rate has reached the maximum rate, wherein
the correction unit is to correct the errors via a memory subsystem redundancy mechanism, the mechanism including at least one of chip spare, rank spare and mirroring.

4. The device of claim 1, wherein,
the detection unit is to count the number of errors according to at least one of a moving average a total number of errors, wherein
the total number of errors is recalculated after the refresh rate is changed.

5. The device of claim 1, wherein,
the maximum rate is based on a capability of a chipset, and
at least one of the normal rate and the error threshold is based on a user's performance requirements.

6. The device of claim 1, wherein,
the detection unit is to poll the RAM for the errors, and
the detection unit includes a counter that is incremented by a number of the errors detected after the RAM is polled.

7. The device of claim 6, wherein an interval of the poll is based on at least one of reliability requirements and error storage capabilities.

8. The device of claim 1, wherein,
the detection unit is to detect the errors by checking error-correcting codes (ECC) of memory cells, and
the detection unit is to write to a Control and Status Register (CSR) after the errors are detected.

9. The device of claim 1, wherein,
the RAM is a dynamic RAM (DRAM),
the detected errors are soft, correctible errors, and
the errors are detected while the device is an active state.

10. A method, comprising:
scanning a random-access memory (RAM) for errors;
counting a number of the errors found in the scanned RAM;
increasing a refresh rate, if the number of errors is greater than an error threshold and the refresh rate is not at a maximum rate; and
setting the refresh rate to be a normal rate, if the number of errors is less than or equal to an error threshold, wherein
the scanning and the counting are repeated after the increasing, and
the increasing is repeated if the number of errors stays above the error threshold.

11. The method of claim 10, further comprising:
correcting the errors if the number of errors is greater than an error threshold and the refresh rate is at the maximum rate, wherein
the errors are corrected via a memory subsystem redundancy mechanism.

12. The method of claim 10, wherein the scanning and the counting are repeated at continuous intervals after the setting, while the number of errors remains below or equal to the error threshold.

13. A non-transitory computer-readable storage medium storing instructions that, if executed by a processor of a device, cause the processor to:
set a refresh rate at a normal rate;
scan a random-access memory (RAM) for errors, each error to indicate a memory cell of the RAM that stores incorrect data;
compare a total number of errors in the RAM to an error threshold;
increase the refresh rate if the total number of errors is greater than the error threshold and refresh rate is less than a maximum rate; and
reset the refresh rate to the normal rate if the total number of errors is less than or equal to the error threshold.

14. The non-transitory computer-readable storage medium of claim 13, wherein,
the RAM is scanned for errors after the refresh rate is increased; and
the total number of errors is compared to the error threshold after refresh rate is increased.

15. The non-transitory computer-readable storage medium of claim 14, wherein,
the refresh rate is increased by a multiple of the normal rate, and
the multiple is increased in value if the total number of errors remains greater than the error threshold after the refresh rate is increased.
